(19) United States
(12) Patent Application Publication
(10) Pub. No.: US 2024/0094240 A1
(43) Pub. Date: Mar. 21, 2024

(54) OPTOMECHANICAL TRANSDUCER

(71) Applicants: CENTRE NATIONAL DE LA RECHERCHE SCIENTIFIQUE, Paris (FR); UNIVERSITE DE CAEN NORMANDIE, Caen (FR); UNIVERSITE D'ANGERS, Angers (FR); ECOLE NATIONALE SUPERIEURE D'INGENIEURS DE CAEN, Caen (FR)

(72) Inventors: Cyprien LEMOUCHI, Ouistreham (FR); Régis BARILLE, Angers (FR); Arnaud TRAVERT, Caen (FR); Loïc LE PLUART, Saint Germain la Blanche Herbe (FR)

(21) Appl. No.: 18/262,962

(22) PCT Filed: Jan. 21, 2022
(86) PCT No.: PCT/EP2022/051407

§ 371 Date: Jul. 26, 2023

(30) Foreign Application Priority Data
Feb. 6, 2021 (FR) FR2101161

(51) Int. Cl. G01Q 10/04; C09J 4/00; G01Q 60/32; G01Q 70/14

(52) U.S. Cl. CPC G01Q 10/045; C09J 4/00; G01Q 60/32; G01Q 70/14; H03H 9/215

(57) ABSTRACT

An optomechanical transducer, including a tuning fork made of piezoelectric material including two arms, at least one photoactive film partially deposited on at least one part of at least one of the arms of the tuning fork, the at least one photoactive film including photo-switchable molecules, suitable for molecular switching between a first molecular configuration and a second molecular configuration in response to the absorption of light at a defined, so-called photo-isomerisation wavelength, so that the photoactive film undergoes a shape change that induces a change in the stiffness coefficient of the tuning fork is disclosed. A probe is also provided for a frequency modulation atomic force microscope and to such a microscope.

### TECHNICAL FIELD

The present invention relates to an optomechanical transducer comprising a tuning fork made from piezoelectric material. It also relates to a probe for an atomic force microscope using such a transducer, as well as a frequency modulation atomic force microscope implementing such a probe.

The field of the invention is, non-limitatively, that of nanometric surface metrology.

### STATE OF THE ART

Atomic force microscopes (AFMs) used for producing topographies of the surfaces of samples are known. An example is the frequency modulation AFM (FM-AFM) making it possible to map the surface of the sample without contact by using a single system to generate the vibration frequency of the probe of the AFM and the detection of its modulation induced by the surface investigated. An FM-AFM is particularly suitable for soft or sticky samples, as there is no risk of the tip of the probe remaining caught on the surface thereof, or breaking.

In fields such a materials science and biology, it is fundamental to be able to characterize the topography of the samples finely. In order to obtain a good resolution with an FM-AFM, it is necessary for the probe to be brought into very close proximity with the surface. However, as a result of the forces being exerted between the surface and the tip, the vibration frequency increases undesirably, causing a reduction in the resolution and making it impossible to observe the topographical details of samples.

In order to be able to investigate samples with variable properties (liquid, solid, viscous, rigid, flexible, etc.), it is generally necessary to change the tip. As a consequence, it is impossible to carry out a topographical analysis with a constant high resolution on a sample containing liquid and solid phases for example, as is often the case for biological systems or multi-phase materials (for example, cell media). Modifying an AFM or FM-AFM tip for measuring this type of heterogeneous and/or liquid samples is difficult to carry out.

There are techniques for controlling the vibration frequency of the FM-AFM probe in order to bring it closer to the surface to be probed. One of these techniques includes the use of a piezoelectric element. However, an additional item of equipment, with respect to the FM-AFM control system, is necessary to control the piezoelectric element, making the manufacture and implementation of such a probe complex and costly.

The aim of the present invention is to have available an optomechanical transducer, in particular that can be used in an FM-AFM, making it possible to overcome at least one of the drawbacks described.

### DISCLOSURE OF THE INVENTION

An aim of the present invention is to propose an optomechanical transducer the mechanical movement of which can be adjusted with precision.

Another aim of the present invention is to propose an optomechanical transducer capable of being implemented in a frequency modulation atomic force microscope.

Yet another aim of the present invention is to propose a probe for a frequency modulation atomic force microscope, comprising such a transducer and making it possible to improve the resolution of the microscope.

At least one of these aims is achieved with an optomechanical transducer, comprising:
a tuning fork made from piezoelectric material comprising two arms,
at least one photoactive film deposited partially on at least a part of at least one of the arms of the tuning fork,
the at least one photoactive film comprising photo-switchable molecules, suitable for a molecular switching between a first molecular configuration and a second molecular configuration in reaction to the absorption of light of a defined wavelength, called photo-isomerization wavelength, such that the photoactive film is subjected to a shape change, inducing a modification of the stiffness coefficient of the tuning fork.

The transducer according to the invention utilizes a tuning fork. A tuning fork has a resonance vibration frequency that is characteristic of its geometrical and mechanical properties, and in particular its stiffness. The resonance frequency can also be modified by external forces.

The transducer according to the invention makes it possible to control the change of resonance frequency by modifying the stiffness coefficient of the tuning fork. To this end, at least one film comprising photo-switchable molecules is deposited partially on the tuning fork, such that the film is partly fixed on the tuning fork, the other part of the film remaining free.

The photo-switchable molecules are subjected to a structural modification or a change of configuration under the action of light of photo-isomerization wavelength, indicated by the deformation of the photoactive film placed on the tuning fork. In fact, the free part of the film can move under the effect of the photo-isomerization light. Thus, by virtue of the part deposited on the tuning fork, the optomechanical movement is fully coupled to the tuning fork. This deformation makes it possible to modify the stiffness coefficient of the tuning fork.

Variation of the stiffness coefficient leads to variation in the resonance frequency of the tuning fork, and vice versa. The resonance frequency of the tuning fork also varies as a function of the intensity of the photo-isomerization irradiation. Thus, it is possible to modulate the vibration frequency of the tuning fork precisely in real time according to the desired application of the transducer.

A tuning fork is a component that is inexpensive and easy to mass-produce. The material of the film comprising photo-switchable molecules can also be produced in large quantity in a synthesis laboratory without the need for specific installations or items of equipment.

The at least one photoactive film can be deposited on the tuning fork for example in the form of strips or strands, or for example by dip-coating.

One or more photoactive films can be deposited on the tuning fork. It is thus possible to induce different changes in stiffness, as a function of the position of the films on the tuning fork.

By way of example, pieces or strips of photoactive film have dimensions of the order of one millimetre, for example 1-2 mm wide and 3-4 mm long.

The light at the photo-isomerization wavelength of the photo-switchable molecules can also be called hereinafter photo-isomerization irradiation or photo-isomerization light, or equivalent.

By the term “optomechanical” is meant that the energy of the light radiation, at the photo-isomerization wavelength, is converted into mechanical energy of each photoactive film, when the latter deforms.

According to an advantageous embodiment, the at least one photoactive film comprises at least one self-assembled layer comprising photo-switchable molecules.

A molecular self-assembly system is characterized by the fact that the molecules are organized in layers. This self-organization makes it possible to increase the effect of the photo-isomerization and therefore the degree of deformation of the photoactive film.

According to an example implementation, the at least one photoactive film comprises a molecular system based on azobenzenes.

In fact, azobenzenes are molecules the photo-switching of which is well controlled.

Alternatively, the photo-switchable molecules can include compounds such as: spiropyran, spiro-oxazine, diarylethenes, etc.

Advantageously, the molecular system based on azobenzenes can be organized in molecular stacks.

The shape change of a photoactive film can be indicated by an undulation, a torsion or a flexion of the film.

According to an embodiment, the at least one photoactive film can be deposited on the tuning fork by means of an adherent material.

The adherent material ensures the total adherence of the part of the photoactive film fixed on the tuning fork, the other part of the film remaining free to be able to move under the effect of the photo-isomerization light.

This adherent material can be, for example, glycerine, or another very viscous adherent material.

According to embodiments, the at least one photoactive film is configured to resume its initial shape as a reaction:
to the absence of light at the photo-isomerization wavelength;
to the presence of white light; and/or
to the presence of heat.

According to another aspect of the same invention, a probe is proposed for a frequency modulation atomic force microscope, the probe comprising a photomechanical transducer according to the invention, in which one of the arms of the tuning fork is configured to interact with atoms of a surface to be probed.

The probe according to the present invention can be used to adapt existing FM-AFMs. For this purpose, it is sufficient to replace the existing probe in the microscope with the probe according to the present invention, for example by depositing pieces or strips of a photoactive film on the tip of the existing probe. It is also necessary to provide a light source (and optionally filters) to supply the photo-isomerization irradiation. This would make it possible in particular for these FM-AFMs to measure liquid samples.

The rigidification of the tuning fork following the change in its stiffness coefficient makes it possible to bring the probe closer to the surface of the sample to be measured and therefore to probe objects having smaller dimensions or exerting more intense probe-surface interaction forces. The resolution of an FM-AFM can thus be increased by virtue of such a probe.

According to an embodiment, the probe also comprises a nanometric tip fixed to the end of one of the arms of the tuning fork of the transducer, configured to interact with atoms of a surface to be probed.

Alternatively, the end of one of the arms of the tuning fork can act as a “tip” in order to interact with atoms of a surface to be probed.

Advantageously, the resonance frequency of the tuning fork varies as a function of the intensity of the photo-isomerization irradiation. Thus, any type of sample can be subjected to topographical investigation without changing the tip. This allows in particular topographical analyses on samples composed of liquid and of solid, for example biological or dynamic systems, for which the resonance frequency can then be adapted in real time.

Advantageously, the probe according to the present invention can be miniaturized, in particular by manufacturing nano- or microfibres of the photoactive material deposited on the tuning fork.

According to yet another aspect of the same invention, a frequency modulation atomic force microscope is proposed, comprising a probe according to the present invention, the transducer being attached to one end of a lever.

Such a frequency modulation atomic force microscope according to the invention can be implemented in many surface metrology applications.

It allows measurements in liquids by adapting the stiffness coefficient of the probe in real time to the liquid-solid interfaces probed. Biological systems can thus be easily investigated.

Heterogeneous samples having liquid and solid portions can be measured with the same probe. This is important in particular for the observation of materials in suspension or biological systems contaminated or polluted by particles.

For the measurements, the amplitude of the stiffness coefficient of the tip can be modulated. For example, in non-contact mode, the rate of reflection or of transmission of light by the surface of the sample can be used to distinguish the surface materials, and thus to modulate the stiffness coefficient of the tip as a function of the materials.

Thus, the implementation of the transducer according to the present invention in an AFM allows the production, in reflection mode, of a cartography of the surface of a sample while distinguishing the different types of constituents of a mixture as a function of their refractive index. Currently, this distinguishing is carried out as a function of the hardness of the constituent. Thus, the different constituents can be differentiated if they have the same hardness, making it possible to improve the investigation of compounds in solution, such as in biology.

### DESCRIPTION OF THE FIGURES AND EMBODIMENTS

Other advantages and characteristics will become apparent on examining the detailed description of examples that are in no way limitative, and from the attached drawings, in which:

FIG. 1 shows a diagrammatic representation and a photograph of a non-limitative embodiment example of a transducer according to the invention;

FIG. 2 shows an example of azobenzene molecules capable of being synthesized for the preparation of the photoactive film implemented in an embodiment of the invention;

FIG. 3 shows representations of an example of self-assembled layers of photo-switchable molecules capable of being implemented in an embodiment of the invention;

FIG. 4 represents an example implementation of a transducer according to the present invention; and

FIG. 5 shows an example implementation of a transducer according to an embodiment of the invention in a probe for an atomic force microscope.

It is well understood that the embodiments that will be described hereinafter are in no way limitative. Variants of the invention can be envisaged in particular comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In particular, all the variants and all the embodiments described can be combined together if there is no objection to this combination from a technical point of view.

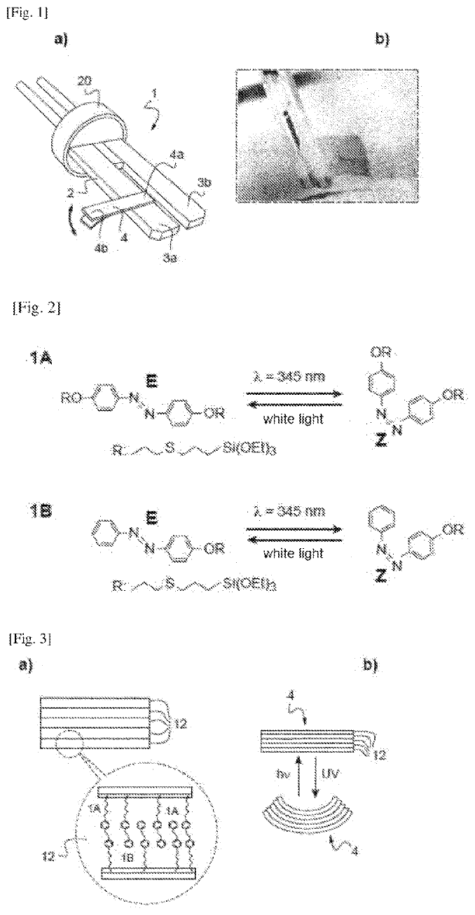

In the figures, elements common to several figures may retain the same reference.

[FIG. 1] shows a diagrammatic representation (a) as well as a photograph (b) of a photomechanical transducer according to an embodiment of the invention.

The transducer 1, as shown in [FIG. 1](a), comprises a tuning fork 2 made from piezoelectric material. A photoactive film is deposited on one of the two arms 3a, 3b of the tuning fork 2. A part 4a of the film is fixed on the arm 3a of the tuning fork 2, and the other part 4b of the film 4 remains free.

In [FIG. 1](a), the transducer 1 is shown with a mounting base 20.

The tuning fork 2 is preferably made from quartz.

The photoactive film 4 comprises photo-switchable molecules. Such molecules are suitable for performing molecular switching between a first molecular configuration and a second molecular configuration in reaction to the absorption of light of a defined wavelength, called photo-isomerization wavelength. The second molecular configuration leads to a shape change of the film 4.

As shown in [FIG. 1], the photoactive film 4 is deposited only on a distal part of one of the arms 3a of the tuning fork 2. Of course, other configurations are possible. For example, the film 4 can be deposited closer to the base of the tuning fork 2, or the two arms 3a, 3b can be equipped with a film 4. The geometry of the film 4 (length, width) can also be varied.

The film 4 is deposited on the tuning fork 2 by means of an adhesive material. This adhesive material is of the soft and viscous type. It can in particular comprise glycerine.

According to a preferred embodiment, les photo-switchable molecules comprise azobenzene units.

Examples of two azobenzene molecules TA, 1B capable of being used for the preparation of the photoactive film within the context of the present invention are shown in [FIG. 2]. The photoactive film can, for example, be made from an azobenzene alkoxysilane-based hybrid material. The molecules are shown in the two configurations E and Z. The synthesis of the molecules and the preparation of such a material are described, for example, in the documents S. Guo et al., RSC Adv., 2014, 4, 25319; S. Guo et al., J. Mater. Chem. C, 2013, 1, 6989; and S. Guo et al., J. Am. Chem. Soc., 2015, 137, 15434.

The switching between the molecular configuration E and the molecular configuration Z is induced by the illumination of the molecules with a radiation at a photo-isomerization wavelength. In the case shown in [FIG. 2], this wavelength is 345 nm.

The switching between the isomer Z and the isomer E is induced by white light.

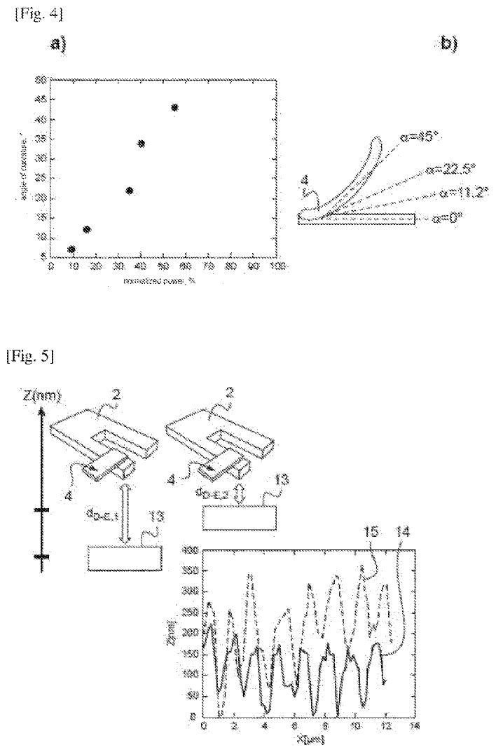

The molecular system based on azobenzenes presents in self-assembled layers. This self-organization of the molecules allows a deformation effect of the film that is greater in the presence of the photo-isomerization irradiation. An example of self-assembled layers 12 is shown in [FIG. 3](a). In this example, 5 layers are shown. A self-assembled layer 12 of alkoxysilane molecules of azobenzene TA, 1B is shown in detail.

[FIG. 3](b) shows diagrammatically a photoactive film 4 comprising self-assembled layers of azobenzenes, indicated by a plurality of layers 12. The film 4 is shown without (top) and with (bottom) illumination at the photo-isomerization wavelength.

When the film 4 is illuminated with light at the photo-isomerization wavelength (here the UV range), the film 4 deforms by curving and folding on itself, under the effect of the molecular switching. In fact, the change of configuration (E to Z) of the molecules leads to an increase of the free volume occupied by the molecules, which is indicated by an elongation of the layer that they compose. As the film 4 only partially adheres to the tuning fork, the free part of the film 4 curves. The tuning fork is then subjected to a change of its stiffness coefficient.

The deformation of the film 4 persists as long as the photo-isomerization radiation is incident on the film 4.

When the photo-isomerization illumination ceases, the film 4 returns to its original shape. The film 4 can in particular be exposed to white light. This is illustrated by the arrow hv in [FIG. 3](b). The film 4 can also return to its initial shape under the effect of heat.

The movement performed by the film 4 during the photo-isomerization and when this ceases is shown in [FIG. 1](a) by an arrow.

[FIG. 4](a) shows the dependence of the angle of curvature of the photoactive film 4 on the power of the photo-isomerization irradiation. An angle of 0° corresponds to a flat film 4, without any curvature ([FIG. 4](b)). Other examples of angles are given by way of illustration. The greater the intensity of the irradiation, the more pronounced is the curvature of the film. A greater curvature of the film 4 leads to a greater increase in the stiffness coefficient of the tuning fork on which the film 4 is deposited.

The resonance frequency of the tuning fork f₀ depends on its mass m as well as its stiffness coefficient k according to the following equation:

$$\\ \begin{matrix}{f}_{0} = \frac{1}{2 π} \sqrt{\frac{k}{m}} . & [ Math 1 ]\end{matrix}$$

It is therefore possible to vary the resonance frequency by varying the stiffness coefficient of the tuning fork.

This mechanism is particularly beneficial when the transducer according to the invention is implemented in a probe for a frequency modulation atomic force microscope (FM-AFM). The tuning fork is then made to vibrate at its resonance frequency, which is controlled. When the transducer is brought towards the surface to be probed, forces being exerted between one end of the tuning fork and the surface modify the vibration frequency of the tuning fork. This frequency shift is used to reconstitute the topography of the surface.

In order to increase the resolution of the FM-AFM, it is necessary to reduce the distance between the surface to be measured and the probe. This involves increasing the vibration frequency f of the tuning fork due to the appearance of repulsive forces, particularly of the van der Waals type. In order to compensate for this effect and to retain the difference between the vibration frequency and the small resonance frequency, the stiffness coefficient and consequently, the resonance frequency of the tuning fork are modified by the photo-isomerization of one or more photoactive films present thereon. Thus, the distance between the tuning fork and the surface to be probed can be reduced.

In fact, the rigidification of the tuning fork makes it possible for the transducer to be brought closer to the surface to be probed, and to obtain a better resolution in order to detect smaller structures.

[FIG. 5] shows an example implementation of a transducer 1 according to an embodiment of the invention in a probe for an FM-AFM. When the photoactive film 4 is not illuminated, the tuning fork 2 can be brought towards the surface 13 of the sample to a distance of d__{D-E,1}, and when it is illuminated at the photo-isomerization wavelength, the tuning fork 2 can be brought towards the surface 13 of the sample to a distance of d__{D-E,2}<d__{D-E,1}. It is noted that the amplitude 15 of the distance Z for the illuminated film is greater than the amplitude 14 of Z for the non-illuminated film. This therefore makes it possible to measure the surface of the sample with a higher resolution.

According to an embodiment, a probe according to the present invention for an FM-AFM comprises an optomechanical transducer as described above. One end of the tuning fork, and in particular at least the end of one of its arms, then interacts with atoms of the surface to be probed, as illustrated in [FIG. 5].

According to another embodiment, the probe according to the present invention can also comprise a nanometric tip fixed to the end of one of the arms of the tuning fork of the transducer. It is then the nanometric tip that interacts with the atoms of the surface to be probed.

Of course, the invention is not limited to the examples that have just been described, and numerous modifications may be made to these examples without exceeding the scope of the invention.

1. An optomechanical transducer comprising:
a tuning fork made from piezoelectric material comprising two arms;
at least one photoactive film deposited partially on at least a part of at least one of the arms of the tuning fork; and the at least one photoactive film comprising photo-switchable molecules, suitable for a molecular switching between a first molecular configuration and a second molecular configuration in reaction to the absorption of light of a defined wavelength, called photo-isomerization wavelength, such that the photoactive film is subjected to a shape change, inducing a modification of the stiffness coefficient of the tuning fork.

2. The transducer according to claim 1, characterized in that the at least one photoactive film comprises at least one self-assembled layer comprising photo-switchable molecules.

3. The transducer according to claim 1, characterized in that the at least one photoactive film comprises a molecular system based on azobenzenes.

4. The transducer according to claim 1, characterized in that the at least one photoactive film is deposited on the tuning fork by means of an adherent material.

5. The transducer according to claim 4, characterized in that the adherent material comprises glycerine.

6. The transducer according to claim 1, characterized in that the at least one photoactive film is configured to resume its initial shape as a reaction:
to the absence of light at the photo-isomerization wavelength;
to the presence of white light; and/or
to the presence of heat.

7. A probe for a frequency modulation atomic force microscope, the probe comprising an optomechanical transducer according to claim 1, in which one of the arms of the tuning fork is configured to interact with atoms of a surface to be probed.

8. The probe according to claim 7, also comprising a nanometric tip fixed to the end of one of the arms of the tuning fork of the transducer, configured to interact with atoms of a surface to be probed.

9. A frequency modulation atomic force microscope, comprising the probe according to claim 7, the transducer being attached to one end of a lever.
